(19) United States
(12) Patent Application Publication
(10) Pub. No.: US 2026/0341371 A1
(43) Pub. Date: Oct. 29, 2026

(54) MEMORY CONTROLLER AND STORAGE DEVICE INCLUDING THE SAME

(71) Applicant: SK hynix Inc., Gyeonggi-do (KR)

(72) Inventor: Han Bin LEE, Gyeonggi-do (KR)

(21) Appl. No.: 19/366,539

(22) Filed: Oct. 23, 2025

(30) Foreign Application Priority Data
Apr. 29, 2025 (KR) 10-2025-0056194

(51) Int. Cl. G11C 16/26; G11C 16/20; G11C 16/32

(52) U.S. Cl. CPC G11C 16/26; G11C 16/20; G11C 16/32

(57) ABSTRACT

A memory controller, controlling a memory device including a plurality of memory blocks, is configured to read identification (ID) data stored in the memory device upon power-on, checks an address cycle set for the memory device based on the ID data, and reads, during the address cycle, address data of a firmware block in which boot loader firmware is stored among the plurality of memory blocks.

### CROSS-REFERENCE TO RELATED APPLICATIONS

The present application claims priority under 35 U.S.C. § 119(a) to Korean patent application number 10-2025-0056194, filed on Apr. 29, 2025, the entire disclosure of which is incorporated herein by reference.

### BACKGROUND

### 1. Technical Field

Various embodiments of the present disclosure generally relate to a memory controller, and more particularly, to a memory controller and a storage device including the same.

### 2. Related Art

A storage device is a device which stores data under the control of a host device, such as a computer, smartphone, or smart pad. The storage device may include a memory device in which data is stored, and a memory controller which stores data in the memory device. The memory device may be classified as a volatile memory device or a non-volatile memory device.

The memory controller may output a clock signal to the memory device. The memory controller may receive data in units of 1 byte for each cycle of the clock signal. The memory controller may receive address information for a particular memory block in the memory device over a plurality of cycles of the clock signal. The memory controller needs to determine the number of cycles based on information set for the memory device.

### SUMMARY

Various embodiments of the present disclosure are directed to a memory controller which determines the number of cycles for receiving address information based on information set for a memory device, and a storage device including the memory controller.

A memory controller according to embodiments of the present disclosure may control a memory device including a plurality of memory blocks. The memory controller may read identification (ID) data stored in the memory device upon power-on, may check an address cycle set for the memory device based on the ID data, and may read, during the address cycle, address data of a firmware block in which boot loader firmware is stored among the plurality of memory blocks.

In embodiments, the memory controller may determine, based on the ID data, the address cycle to be one of a first cycle or a second cycle and may read the address data during the determined address cycle.

In embodiments, the memory controller may compare a bit value of an address field of the ID data with a reference bit value, and may determine the address cycle to be one of the first cycle or the second cycle based on the comparison.

In embodiments, the memory controller may determine the first cycle as the address cycle when the bit value of the address field is the same as the reference bit value, and may determine the second cycle as the address cycle when the bit value of the address field is not the same as the reference bit value.

In embodiments, the memory controller may output a clock signal to the memory device and may read the address data from the memory device in units of 1 byte for each cycle of the clock signal, and the address cycle may be a number of cycles of the clock signal used for the memory controller to read the address data.

In embodiments, the memory controller may read, when the address cycle is the first cycle, the address data over a number of cycles of the clock signal of the first cycle, and may read, when the address cycle is the second cycle, the address data over a number of cycles of the clock signal of the second cycle.

In embodiments, the memory controller may access the firmware block based on the read address data, may read the boot loader firmware stored in the firmware block, and may boot the memory device based on the boot loader firmware.

In embodiments, the memory controller may output a read command for reading the ID data to the memory device, and the ID data may be included in a data signal received in a third cycle of the clock signal among data signals received in response to the read command.

In embodiments, the address field may be one of a plurality of fields included in the ID data.

In embodiments, the address field may be a last field of the plurality of fields.

A storage device according to embodiments of the present disclosure may include a plurality of memory devices; and a memory controller. The memory controller may read, upon power-on, address data of a memory block in which boot loader firmware of each of the plurality of memory devices is stored, according to an address cycle set for each of the plurality of memory device.

In embodiments, the address cycle for each of the plurality of memory devices may be set to be a first cycle or a second cycle.

In embodiments, the memory controller may read, for a first memory device for which a first address cycle is set, among the plurality of memory devices, first address data of a memory block in which boot loader firmware of the first memory device is stored during the first address cycle; and may read for a second memory device for which a second address cycle is set, among the plurality of memory devices, second address data of a memory block in which boot loader firmware of the second memory device is stored during the second address cycle.

In embodiments, the memory controller may read first ID data stored in the first memory device during the power-on, and may check, based on the first ID data, the first address cycle set for the first memory device.

In embodiments, the memory controller may compare a bit value of an address field of the first ID data with a reference bit value, and may determine the first address cycle to be one of the first cycle or the second cycle.

In embodiments, the memory controller may determine the first cycle as the first address cycle when the bit value of the address field is the same as the reference bit value, and may determine the second cycle as the first address cycle when the bit value of the address field is not the same as the reference bit value.

In embodiments, the memory controller may output a clock signal to the first memory device, and may read the first address data from the first memory device in units of 1 byte for each cycle of the clock signal. The first address cycle may be a number of cycles of the clock signal used for the memory controller to read the first address data.

In embodiments, the memory controller may read, when the first address cycle is the first cycle, the first address data over a number of cycles of the clock signal of the first cycle, and may read, when the first address cycle is the second cycle, the first address data over a number of cycles of the clock signal of the second cycle.

In embodiments, the memory controller may access, based on the read first address data, the memory block in which the boot loader firmware of the first memory device is stored; may read the boot loader firmware stored in the memory block; and may boot the first memory device based on the boot loader firmware.

In embodiments, the memory controller may output a read command for reading the first ID data to the first memory device, and the first ID data may be included in a data signal received in a third cycle of the clock signal among data signals received in response to the read command.

### BRIEF DESCRIPTION OF THE DRAWINGS

FIG. 1 is a block diagram of an electronic system according to embodiments of the present disclosure;

FIG. 2 is a detailed block diagram illustrating a signal transmission path between a memory controller and a memory device;

FIG. 3 is a diagram illustrating a memory hierarchy of a storage device according to embodiments of the present disclosure;

FIG. 4 is a detailed block diagram illustrating a memory device of FIG. 1, according to embodiments of the present disclosure;

FIG. 5 is a detailed block diagram illustrating a memory controller of FIG. 1, according to embodiments of the present disclosure;

FIG. 6 is a flowchart illustrating a boot operation according to embodiments of the present disclosure;

FIG. 7 is a flowchart illustrating an address cycle check operation according to embodiments of the present disclosure;

FIG. 8 is a diagram illustrating fields of third ID data according to embodiments of the present disclosure;

FIG. 9 is a flowchart illustrating a boot operation according to embodiments of the present disclosure;

FIG. 10 is a flowchart illustrating an internal parameter read operation and a status monitoring operation according to embodiments of the present disclosure;

FIG. 11 is a block diagram illustrating a memory card system to which a storage device according to embodiments of the present disclosure is applied; and

FIG. 12 is a block diagram illustrating an example of a Solid State Drive (SSD) system to which a storage device according to embodiments of the present disclosure is applied.

### DETAILED DESCRIPTION

Hereinafter, embodiments according to the present disclosure are described in detail with reference to the accompanying drawings. It should be noted that in the following description, only portions necessary for understanding an operation according to the present disclosure may be described, and descriptions of other portions may be omitted in order not to obscure the subject matter of the present disclosure. In addition, the present disclosure may be embodied in other forms without being limited to embodiments described herein. However, embodiments of the present disclosure are described in detail in order for those skilled in the art to be able to readily implement the technical spirit of the present disclosure.

Terms used herein are for describing specific embodiments and are not intended to limit the disclosure. Throughout the specification, in a case where a certain portion “includes” a certain component, the portion may further include another component without excluding another component unless otherwise stated. “At least any one of X, Y, or Z” and “at least any one selected from a group consisting of X, Y, and Z” may be interpreted as X only, Y only, Z only, or any combination of two or more of X, Y, and Z (e.g., XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

In this field, some embodiments are described and illustrated in the accompanying drawings in terms of functional blocks, units, parts, and/or modules. Those skilled in the art will understand that these blocks, units, parts, and/or modules are physically implemented by electronic (or optical) circuits, such as logic circuits, discrete components, microprocessors, hard-wired circuits, memory elements, line connections, and the like, which may be formed using semiconductor-based manufacturing techniques or other manufacturing techniques. In a case where the blocks, units, parts, and/or modules are implemented by microprocessors or other similar hardware, they may be programmed and controlled using software (e.g., microcode) to perform the various functions discussed herein, and may optionally be driven by firmware and/or software.

Further, each block, unit, part, and/or module may be implemented by dedicated hardware, or by a combination of dedicated hardware performing some functions and processors (e.g., one or more programmed microprocessors and associated circuits) performing other functions. Further, each block, unit, part, and/or module of some embodiments may be physically separated into two or more interacting and separate blocks, units, parts, and/or modules without departing from the scope of the present disclosure. Further, the blocks, units, parts, and/or modules of some embodiments may be physically combined into more complex blocks, units, parts, and/or modules without departing from the scope of the present disclosure.

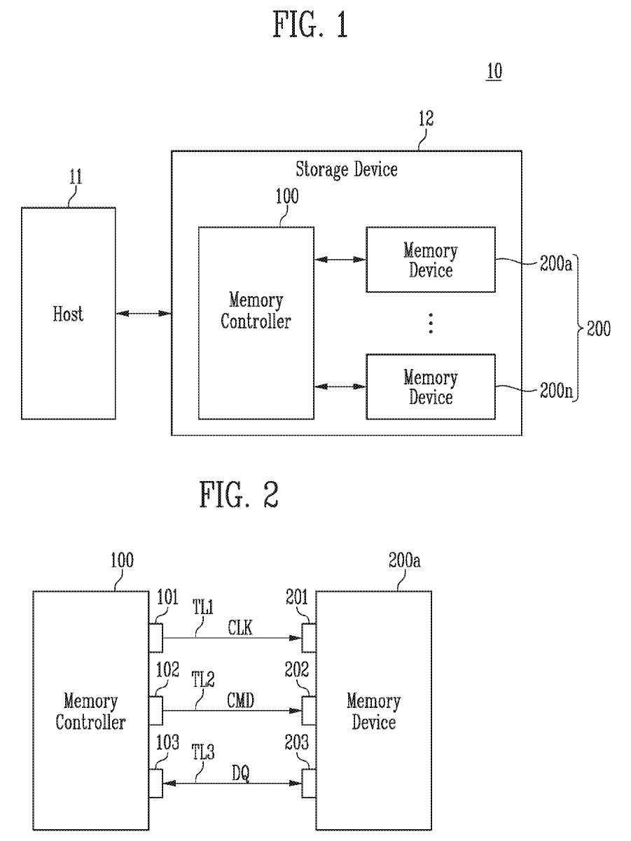

FIG. 1 is a block diagram of an electronic system 10 according to embodiments of the present disclosure.

Referring to FIG. 1, the electronic system 10 may be a computing system configured to process various information and/or store the processed information as data. In some embodiments, the electronic system 10 may be implemented as a personal computer (PC), notebook, laptop, server, workstation, tablet PC, smartphone, digital camera, dashcam, or the like.

The electronic system 10 may include a host 11 and a storage device 12. The host 11 may control various operations of the electronic system 10. More specifically, the host 11 may control operations of other components constituting the electronic system 10. The host 11 may be implemented as a general purpose processor, a dedicated processor, a central processing unit (CPU), an application processor (AP), or the like.

The host 11 may communicate with the storage device 12. For example, the host 11 may request that the storage device 12 perform a program operation, a read operation, an erase operation, or the like. The host 11 may send the storage device 12 a host request, data, and logical address for the program operation of the storage device 12. The host 11 may send the storage device 12 a host request and logical address for the read operation of the storage device 12.

The storage device 12 may store data. For example, the storage device 12 may store the data under the control of the host 11. In some embodiments, the storage device 12 may include at least one of a Solid State Device (SSD), embedded memory, or removable external memory.

When the storage device 12 is an SSD, the storage device 12 may be a device which conforms to a Non-Volatile Memory express (NVMe) standard. When the storage device 12 is embedded memory or removable external memory, the storage device 12 may be a device which conforms to a Universal Flash Storage (UFS) or embedded Multi-Media Card (eMMC) standard. The host 11 and the storage device 12 may each generate packets based on an adopted standard protocol and transfer the generated packets to each other.

The storage device 12 may include a memory controller 100 and a plurality of memory devices 200. The memory controller 100 may control an operation of the storage device 12. For example, the memory controller 100 may control the operation of the storage device 12 in accordance with an internal policy or in response to a request from the host 11. The memory controller 100 may store data in the plurality of memory devices 200 or read data stored in the plurality of memory devices 200 in accordance with the internal policy or in response to the request from the host 11.

In response to a host request corresponding to a program operation which is received from the host 11, the memory controller 100 may generate a program command and provide the generated program command to the plurality of memory devices 200. In response to a host request corresponding to a read operation which is received from the host 11, the memory controller 100 may generate a command and provide the generated command to the plurality of memory devices 200. The memory controller 100 may transfer the data read from the plurality of memory devices 200 to the host 11.

The plurality of memory devices 200 may store data under the control of the memory controller 100. The plurality of memory devices 200 may include a plurality of memory devices 200a to 200n. Each of the plurality of memory devices 200a to 200n may include a plurality of memory blocks. Each of the plurality of memory blocks may include a plurality of memory cells, and the plurality of memory cells may constitute a plurality of strings or a plurality of pages. n may be a natural number greater than 1.

Each of the plurality of memory devices 200ato 200n may move or copy data to perform various functions. For example, each of the plurality of memory devices 200a to 200n may move or copy data between memory blocks of the plurality of memory devices 200a to 200n to perform at least one of a garbage collection operation, a read reclaim operation, a read refresh operation, a wear leveling operation, or an over-provisioning operation.

Each of the plurality of memory devices 200a to 200n may be NAND flash memory, but the scope of the present disclosure is not limited thereto. Each of the plurality of memory devices 200a to 200n may be one of various storage devices which may retain stored data even when the power supply is interrupted, such as Phase-change Random Access Memory (PRAM), Magnetic Random Access Memory (MRAM), Resistive Random Access Memory (RRAM), and Ferroelectric Random Access Memory (FRAM).

As the number of stacks of NAND flash memory increases, the number of bits of address data for the memory controller 100 to access the memory blocks of the plurality of memory devices 200a to 200n may increase. Accordingly, an address cycle may increase.

An address cycle may refer to the number of cycles of a clock signal used to transfer address data between the memory controller 100 and each of the plurality of memory devices 200a to 200n. The memory controller 100 may receive the address data from each of the plurality of memory devices 200a to 200n in units of 1 byte. The memory controller 100 may receive the address data in units of 1 byte for each cycle of the clock signal. For example, an address cycle of ‘5 cycles’ may mean that the memory controller 100 receives address data continuously for 5 cycles of the clock signal.

One or more of the plurality of memory devices 200a to 200n may have an address cycle set to ‘5 cycles’ on a single die basis, while the others of the plurality of memory devices 200a to 200n may have an address cycle set to ‘6 cycles’ to support the increased number of address bits due to the increased number of stacks of the NAND flash memory.

However, when the memory controller 100 is set to receive address data over ‘5 cycles’, the memory controller 100 might not (for example, be configured or able to) access the memory device having the address cycle set to ‘6 cycles’, and when the memory controller 100 is set to receive address data over ‘6 cycles’, the memory controller 100 might not (for example, be configured or able to) access the memory device having the address cycle set to ‘5 cycles’.

Accordingly, there may be a need for the memory controller 100 which may manage the plurality of memory devices 200a to 200n with different address cycles set. The embodiments herein below may contemplate and compensate for the mismatch in configured address cycles and address data between the memory controller 100 and the memory device.

FIG. 2 is a detailed block diagram illustrating a signal transmission path between the memory controller 100 and the memory device 200a in accordance with an embodiment of the present disclosure.

Referring to FIG. 2, the memory controller 100 of FIG. 1 may output a clock signal CLK and a command CMD to the memory device 200a, and the memory controller 100 may transfer and receive data DQ to and from the memory device 200a.

In FIG. 2, only the memory device 200a of the plurality of memory devices 200a to 200n is illustrated, but each of the plurality of memory devices 200a to 200n may communicate with the memory controller 100 in a similar manner to the memory device 200a.

The memory controller 100 and the memory device 200a may be coupled to each other via clock pins 101 and 201, command pins 102 and 202, and data pins 103 and 203, each forming a corresponding pair between the memory controller 100 and the memory device 200a. The memory controller 100 may output the clock signal CLK to the memory device 200a via the clock pins 101 and 201 and a clock transmission line TL1. The memory controller 100 may output a command CMD signal to the memory device 200a via the command pins 102 and 202 and a command transmission line TL2. The memory controller 100 may output the data DQ to the memory device 200a via the data pins 103 and 203 and a data transmission line TL3, or receive the data DQ from the memory device 200a via the data pins 103 and 203 and the data transmission line TL3.

The clock pins 101 and 201 and the clock transmission line TL1 may be referred to as a clock bus, the command pins 102 and 202 and the command transmission line TL2 may be referred to as a command bus, and the data pins 103 and 203 and the data transmission line TL3 may be referred to as a data bus.

Referring to FIGS. 1 and 2, the memory controller 100 may receive address data from the memory device 200a in units of 1 byte for each cycle of the clock signal CLK. In embodiments, the memory device 200a may output address data of a firmware memory block storing data used for booting firmware to the memory controller 100 via the data bus in units of 1 byte for each cycle of the clock signal CLK.

While FIG. 2 illustrates the clock bus, the command bus, and the data bus coupling the memory controller 100 and the memory device 200a, the present disclosure is not limited thereto, and additional buses may be present between the memory controller 100 and the memory device 200a for transmitting and receiving signals other than the clock signal CLK, the command CMD signal, and the data DQ.

In addition, a data strobe signal may be transmitted and received between the memory controller 100 and the memory device 200a via the data bus, and an address signal may be output from the memory controller 100 to the memory device 200a via the command bus.

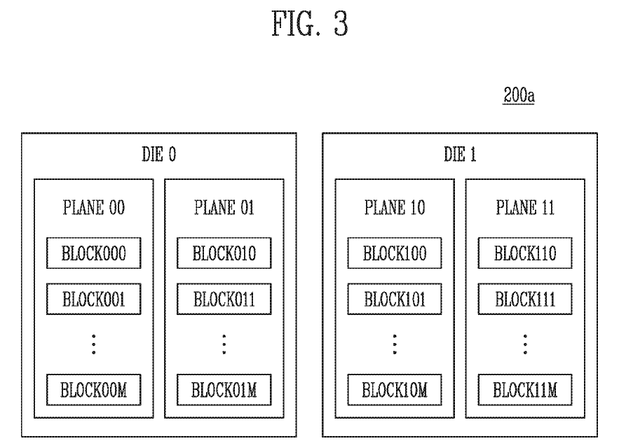

FIG. 3 is a diagram illustrating a memory hierarchy of a storage device according to embodiments of the present disclosure.

Referring to FIG. 3, components included in the memory device 200a of FIG. 1 are illustrated.

In FIG. 3, only the memory device 200a of the plurality of memory devices 200a to 200n is illustrated, but each of the plurality of memory devices 200a to 200n may include components in a similar manner to the memory device 200a.

The memory device 200a may include a plurality of memory dies DIE0 and DIE1. Each of the plurality of memory dies DIE0 and DIE1 may represent a physical semiconductor chip. The plurality of memory dies DIE0 and DIE1 may communicate with the memory controller 100 via respective channels.

Each of the plurality of memory dies DIE0 and DIE1 may include a plurality of planes. For example, a first memory die DIE0 may include a plurality of planes PLANE00 and PLANE01, and a second memory die DIE1 may include a plurality of planes PLANE10 and PLANE11.

Each of the plurality of planes may respectively communicate with the memory controller 100 via various ways. The plurality of planes included in a single memory die may share a channel. For example, a first plane PLANE00 included in the first memory die DIE0 may communicate with the memory controller 100 via a first way and a first channel, and a second plane PLANE01 included in the first memory die DIE0 may communicate with the memory controller 100 via a second way and the first channel.

Each of the plurality of planes may include a plurality of memory blocks. Each of the plurality of memory blocks may be a unit for storing data within the plane.

For example, the first plane PLANE00 of the first memory die DIE0 may include a plurality of memory blocks BLOCK000, BLOCK001, BLOCK002, ..., BLOCK00M. The second plane PLANE01 of the first memory die DIE0 may include a plurality of memory blocks BLOCK010, BLOCK011, BLOCK012, ..., BLOCK01M. A first plane PLANE10 of the second memory die DIE1 may include a plurality of memory blocks BLOCK100, BLOCK101, BLOCK102, ..., BLOCK10M. A second plane PLANE11 of the second memory die DIE1 may include a plurality of memory blocks BLOCK110, BLOCK111, BLOCK112, ..., BLOCK11M. M is a natural number greater than 1.

Each of the plurality of memory blocks may include a plurality of pages. Each of the plurality of pages may be the smallest unit for storing data, and may be a unit for performing read/write operations. Each of the plurality of memory blocks may be a unit for erasing data.

As the number of stacks of the memory device 200a increases, the number of memory dies, planes, memory blocks, and pages included in the memory device 200a may increase. Accordingly, the number of bits of address data for accessing memory blocks or pages in which particular data is stored may increase. As the number of bits of the address data increases, an address cycle may increase.

In FIG. 3, it is illustrated that the memory device 200a includes two memory dies DIE0 and DIE1, and each memory die DIE0/DIE1 includes two planes PLANE00 and PLANE01/PLANE10 and PLANE11, but this is only an embodiment by way of non-limiting example for ease of description. Depending on an embodiment, the memory device 200a may include more or fewer memory dies than two, and each memory die may include more or fewer planes than two.

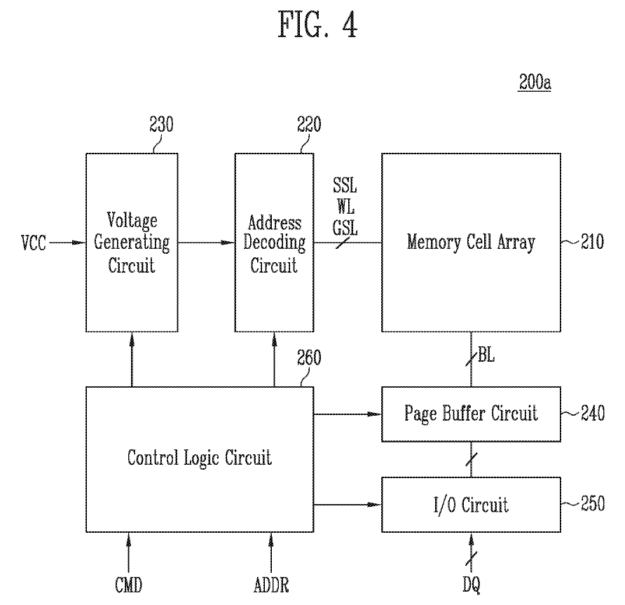

FIG. 4 is a detailed block diagram illustrating the memory device 200a of FIG. 1, according to embodiments of the present disclosure.

Referring to FIG. 4, the memory device 200a may include a memory cell array 210, an address decoding circuit 220, a voltage generating circuit 230, a page buffer circuit 240, an input/output circuit 250, and a control logic circuit 260.

In FIG. 4, only the memory device 200a of the plurality of memory devices 200a to 200n is illustrated, but each of the plurality of memory devices 200a to 200n may include components in a similar manner to the memory device 200a.

In some embodiments, the memory device 200a may be a non-volatile memory device based on NAND flash memory. However, the scope of the present disclosure is not limited thereto, and the memory device 200a may be one of various types of memory devices, such as Dynamic Random Access Memory (DRAM), Static Random Access Memory (SRAM), Phase change RAM (PRAM), Magnetic (or magnetoresistive) RAM (MRAM), Resistive Random Access Memory (RRAM), Ferroelectric Random Access Memory (FRAM), and the like.

The memory cell array 210 may include a plurality of memory blocks. The plurality of memory blocks may be the plurality of memory blocks BLOCK000 to BLOCK11M described with reference to FIG. 3. Each of the plurality of memory blocks may include a plurality of cell strings. Each of the plurality of cell strings may be coupled to the address decoding circuit 220 via row lines and may be coupled to the page buffer circuit 240 via bit lines BL. The row lines may include drain select lines GSL, word lines WL, and source select lines SSL.

Each of the plurality of cell strings may include a plurality of memory cells. The plurality of memory cells may respectively correspond to a plurality of cell transistors coupled in series between the bit lines BL and the select lines. The plurality of cell transistors may be coupled to the drain select lines GSL, the word lines WL, and the source select lines SSL.

In embodiments, the address decoding circuit 220, the voltage generating circuit 230, the page buffer circuit 240, and the input/output circuit 250 may be collectively referred to as a peripheral circuit. The peripheral circuit may drive the memory cell array 210 under the control of the control logic circuit 260. The peripheral circuit may drive the memory cell array 210 to perform a program operation, a read operation, and an erase operation.

The address decoding circuit 220 may be coupled to the memory cell array 210 via the row lines. The address decoding circuit 220 may receive an address ADDR from the control logic circuit 260. The address decoding circuit 220 may decode a block address of the received address ADDR. The address decoding circuit 220 may select at least one memory block of the plurality of memory blocks based on the decoded block address.

The address decoding circuit 220 may decode a row address of the received address ADDR. The address decoding circuit 220 may select at least one word line of word lines of the selected memory block based on the decoded row address. In embodiments, the address decoding circuit 220 may decode a column address of the received address ADDR. The address decoding circuit 220 may couple the input/output circuit 250 and the memory cell array 210 based on the decoded column address.

The voltage generating circuit 230 may generate various voltages used for the memory device 200a to operate. For example, the voltage generating circuit 230 may generate various voltages, such as a plurality of program voltages, a plurality of pass voltages, a plurality of verify voltages, a plurality of selected read voltages, a plurality of unselected read voltages, a plurality of erase voltages, and a plurality of erase verify voltages, based on a power voltage VCC.

The page buffer circuit 240 may be coupled to the memory cell array 210 via the bit lines BL. The page buffer circuit 240 may read data stored in the memory cell array 210 by detecting voltage changes on the bit lines BL, and may temporarily store the read data. The page buffer circuit 240 may receive data from the input/output circuit 250, and may store the data in the memory cell array 210 by controlling the bit lines BL based on the received data.

The input/output circuit 250 may transfer and receive the data DQ to and from an external device (e.g., a memory controller). For example, the input/output circuit 250 may receive the data DQ from an external device and transfer the received data DQ to the page buffer circuit 240. The input/output circuit 250 may receive the data DQ from the page buffer circuit 240 and transfer the received data DQ to the external device.

In embodiments, the memory device 200a may output the data DQ to the memory controller 100 via the data bus of FIG. 2, or the memory device 200a may receive the data DQ from the memory controller 100 via the data bus of FIG. 2.

The control logic circuit 260 may control various operations of the memory device 200a. For example, the control logic circuit 260 may receive the command CMD and the address ADDR from an external device (e.g., a memory controller), generate control signals in response to the command CMD and the address ADDR, and control the peripheral circuit. The peripheral circuit may include the address decoding circuit 220, the voltage generating circuit 230, the page buffer circuit 240, and the input/output circuit 250.

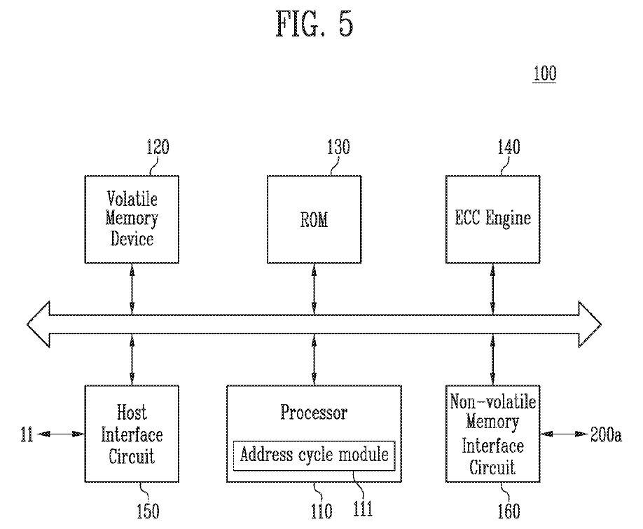

FIG. 5 is a detailed block diagram illustrating the memory controller 100 of FIG. 1, according to embodiments of the present disclosure.

Referring to FIGS. 1 and 5, the memory controller 100 may communicate with the host 11 and the memory device 200a. The memory controller 100 may include a processor 110, a volatile memory device 120, Read Only Memory (ROM) 130, an Error Correction Code (ECC) engine 140, a host interface circuit 150, and a non-volatile memory interface circuit 160.

An address cycle module 111 may check an address cycle set for the memory device 200a and deliver the checked address cycle to the processor 110. Based on the checked address cycle, the processor 110 may receive address data of a firmware block storing boot loader firmware.

The boot loader firmware may include commands used to boot the memory device 200a. For example, the boot loader firmware may include commands related to setting up an initial environment and loading an operating system which are used to boot the memory device 200a.

In embodiments, the memory device 200a may receive 1 byte of data for each cycle of the clock signal CLK. When an address cycle set for the memory device 200a is ‘5 cycles’, the processor 110 may receive 5 bytes of address data from the memory device 200a over 5 cycles of the clock signal CLK. When an address cycle set for the memory device 200a is ‘6 cycles’, the processor 110 may receive 6 bytes of address data from the memory device 200a over 6 cycles of the clock signal CLK.

Based on the received address data, the processor 110 may access the firmware block and may read the boot loader firmware stored in the firmware block. The processor 110 may load a command corresponding to the boot loader firmware stored in the firmware block into the volatile memory device 120 of the memory controller 100, and execute the loaded command to execute the boot loader firmware. The boot loader firmware may handle all initialization tasks to fully boot the memory device 200a, and may handle tasks necessary to load the operating system of the memory device 200a.

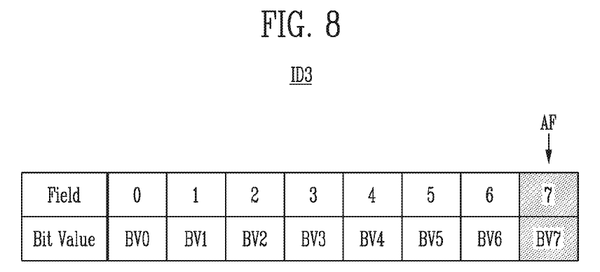

In embodiments, the address cycle module 111 may be implemented in firmware. For example, the ROM 130 may store commands corresponding to the address cycle module 111. The processor 110 may load the commands corresponding to the address cycle module 111 into the volatile memory device 120. By executing the loaded commands, the processor 110 may operate the address cycle module 111. A more detailed description of the address cycle module 111 will be provided below with reference to FIGS. 7 and 8.

The volatile memory device 120 may be used as main memory, cache memory, or operational memory of the memory controller 100. For example, the volatile memory device 120 may be implemented as Static Random Access Memory (SRAM), Dynamic Random Access Memory (DRAM), or the like.

The processor 110 may control various operations of the memory controller 100. The processor 110 may execute firmware and control an operation of the memory controller 100. The processor 110 may execute (run) firmware loaded into the volatile memory device 120 to control the various operations of the memory controller 100 and perform logical operations.

The firmware is a program which runs within the storage device 12 and may include various functional layers. For example, the firmware may include one or more of: a Flash Translation Layer (FTL) which functions to translate between logical addresses requested by the host 11 to the storage device 12 and physical addresses of the plurality of memory devices 200; a Host Interface Layer (HIL) which functions to interpret a command requested by the host 11 to the plurality of memory devices 200 and to deliver the interpreted command to the FTL; and a Flash Interface Layer (FIL) which delivers a command directed by the FTL to the plurality of memory devices 200.

The ROM 130 may be used as read-only memory which stores information used for an operation of the memory controller 100. The ECC engine 140 may detect and correct errors in data read from the memory device 200a. For example, the ECC engine 140 may have a predetermined level of error correction capability. The ECC engine 140 may treat data having an error level (e.g., the number of flipped bits) which exceeds the error correction capability as uncorrectable data.

The memory controller 100 may communicate with the host 11 via the host interface circuit 150. In some embodiments, the host interface circuit 150 may be implemented based on at least one of various interfaces, such as Serial Advanced Technology Attachment (SATA), Peripheral Component Interconnect-Express (PCI-e), a Serial Attached Small Computer System Interface (SAS), an embedded MultiMedia Card (eMMC) interface, and Universal Flash Storage (UFS).

The memory controller 100 may communicate with the memory device 200a via the non-volatile memory interface circuit 160. In some embodiments, the non-volatile memory interface circuit 160 may be implemented based on a NAND flash interface, such as Toggle, or an Open NAND Flash Interface (ONFI).

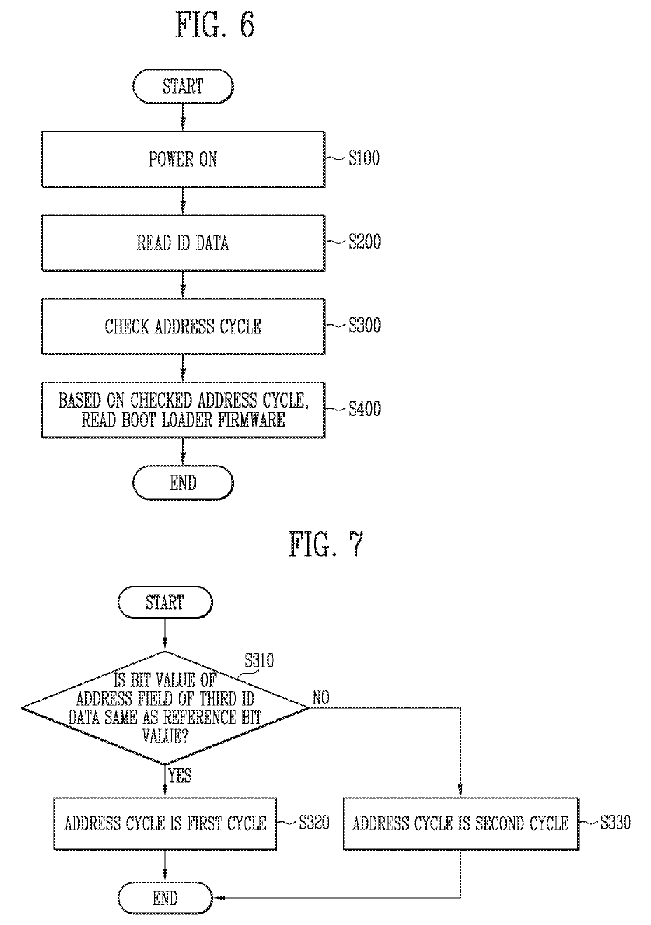

FIG. 6 is a flowchart illustrating a boot operation according to embodiments of the present disclosure.

Referring to FIG. 6, the memory controller 100 of FIG. 1 may perform booting of the memory device 200a according to a boot sequence.

Hereinafter, an operation in which the memory controller 100 performs booting of the memory device 200a among the plurality of memory devices 200 of FIG. 1 via the processor 110 of FIG. 5 is described. Similarly, the memory controller 100 may perform booting of each of the plurality of memory devices 200.

Also, for convenience of description, FIG. 6 illustrates only parts of the boot sequence which are related to the present disclosure. However, according to embodiments, the processor 110 may perform the booting of the memory device 200a by operations not shown in FIG. 6.

At step S100, power may be supplied to the memory controller 100 to activate (power on) the processor 110.

At step S200, ID (identification) data of the memory device 200a may be read. The ID data may include characteristics of the memory device 200a, such as a manufacturer, model number, capacity, and page size of the memory device 200a. The size of ID data may be 1 byte.

In embodiments, the processor 110 may output a read command to the memory device 200a, and the processor 110 may receive data signals from the memory device 200a in response to the read command. The processor 110 may receive the data signals via the data bus of FIG. 2. Each of the data signals may include corresponding ID data.

The processor 110 may receive a data signal for each cycle of the clock signal CLK of FIG. 2. For example, among the data signals received in response to the read command, a data signal received in a first cycle of the clock signal CLK may include first ID data. Among the data signals received in response to the read command, a data signal received in a second cycle of the clock signal CLK may include second ID data. Among the data signals received in response to the read command, a data signal received in a third cycle of the clock signal CLK may include third ID data.

At step S300, the processor 110 may check an address cycle of the memory device 200a. In embodiments, the processor 110 may receive the address cycle of the memory device 200a from the address cycle module 111. An operation of the address cycle module 111 for checking the address cycle of the memory device 200a based on the third ID data will be described below with reference to FIG. 7.

At step S400, the processor 110 may access a firmware block in which boot loader firmware is stored based on the checked address cycle. Based on the checked address cycle, the processor 110 may read address data of the firmware block in which the boot loader firmware is stored. Based on the read address data, the processor 110 may access the firmware block.

The processor 110 may read the boot loader firmware stored in the firmware block. In embodiments, the processor 110 may read the boot loader firmware in a Single Level Cell (SLC) mode. The SLC mode may be a method in which only one bit is stored in one memory cell.

The processor 110 may load the boot loader firmware into the volatile memory device 120 to boot an operating system or additional firmware of the memory device 200a.

As described with reference to FIG. 6, during the boot sequence in which the processor 110 boots the memory device 200a, the processor 110 may check the address cycle of the memory device 200a. Accordingly, the processor 110 may read address data of a firmware block in which boot loader firmware is stored of each of the plurality of memory devices 200, according to an address cycle set for each of the plurality of memory devices 200.

For example, for a first memory device having an address cycle set to a first address cycle among the plurality of memory devices 200, the processor 110 may read address data of a firmware block of the first memory device during the first address cycle. For a second memory device having an address cycle set to a second address cycle among the plurality of memory devices 200, the processor 110 may read address data of a firmware block of the second memory device during the second address cycle.

Accordingly, the memory controller 100 may access the firmware blocks of the plurality of memory devices 200 with different address cycles set, and may boot the plurality of memory devices 200.

FIG. 7 is a flowchart illustrating an address cycle check operation according to embodiments of the present disclosure.

Referring to FIG. 7, an operation in which the address cycle module 111 of FIG. 5 checks the address cycle of the memory device 200a is illustrated.

Hereinafter, an operation in which the memory controller 100 checks the address cycle of the memory device 200a among the plurality of memory devices 200 of FIG. 1 via the address cycle module 111 is described. Similarly, the memory controller 100 may check the address cycle set for each of the plurality of memory devices 200. Additionally, steps S310, S320, and S330, described below, may be included in step S300 of FIG. 6.

At step S310, the address cycle module 111 of the processor 110 may check whether a bit value of an address field of the third ID data is the same as a reference bit value. The third ID data may be included in the data signal received in the third cycle of the clock signal CLK of FIG. 2 among the data signals received in response to the read command.

When the bit value of the address field is the same as the reference bit value, the address cycle module 111 may perform step S320. When the bit value of the address field is not the same as the reference bit value, the address cycle module 111 may perform step S330. For example, the reference bit value may be ‘1’. A detailed description of the address field will be provided below with reference to FIG. 8.

At step S320, the address cycle module 111 may determine that the address cycle is the first cycle. For example, the first cycle may be ‘5 cycles’.

Based on the address cycle being the first cycle, the processor 110 may perform step S400 of FIG. 6. For example, when the first cycle is ‘5 cycles,’ the processor 110 may receive 5 bytes of address data from the memory device 200a over 5 cycles of the clock signal CLK.

At step S330, the address cycle module 111 may determine that the address cycle is the second cycle. For example, the second cycle may be ‘6 cycles’.

Based on the address cycle being the second cycle, the processor 110 may perform step S400 of FIG. 6. For example, when the second cycle is ‘6 cycles,’ the processor 110 may receive 6 bytes of address data from the memory device 200a over 6 cycles of the clock signal CLK. Note that a second cycle is described for ease of description and that an address cycle determination for more than a single additional cycle may be implemented within the concept of the present disclosure (for example, ‘7 cycles’).

FIG. 8 is a diagram illustrating fields of third ID data ID3 according to embodiments of the present disclosure.

In FIG. 8, the third ID data ID3 including eight fields is shown. The third ID data ID3 may be included in the data signal received in the third cycle of the clock signal CLK of FIG. 2 among the data signals received in response to the read command.

The third ID data ID3 may include eight fields. Each of the fields may have a bit value. For example, a zeroth field may have a zeroth bit value BV0, a first field may have a first bit value BV1, a second field may have a second bit value BV2, a third field may have a third bit value BV3, a fourth field may have a fourth bit value BV4, a fifth field may have a fifth bit value BV5, a sixth field may have a sixth bit value BV6, and a seventh field may have a seventh bit value BV7.

In embodiments, the last field (i.e., the seventh field) of the third ID data ID3 may be designated as an address field AF. However, the present disclosure is not limited thereto, and according to embodiments, a field, which is not used to indicate the characteristics of the memory device 200a among fields included in the data signals received in response to the read command, may be designated as the address field AF.

The address cycle module 111 of FIG. 5 may compare the bit value BV7 of the address field AF of the third ID data ID3 with the reference bit value. The reference bit value may be ‘1’.

When the seventh bit value BV7 is the same as the reference bit value, the address cycle module 111 may determine that the address cycle is the first cycle. For example, the first cycle may be ‘5 cycles’.

When the seventh bit value BV7 is not the same as the reference bit value, the address cycle module 111 may determine that the address cycle is the second cycle. For example, the second cycle may be ‘6 cycles’.

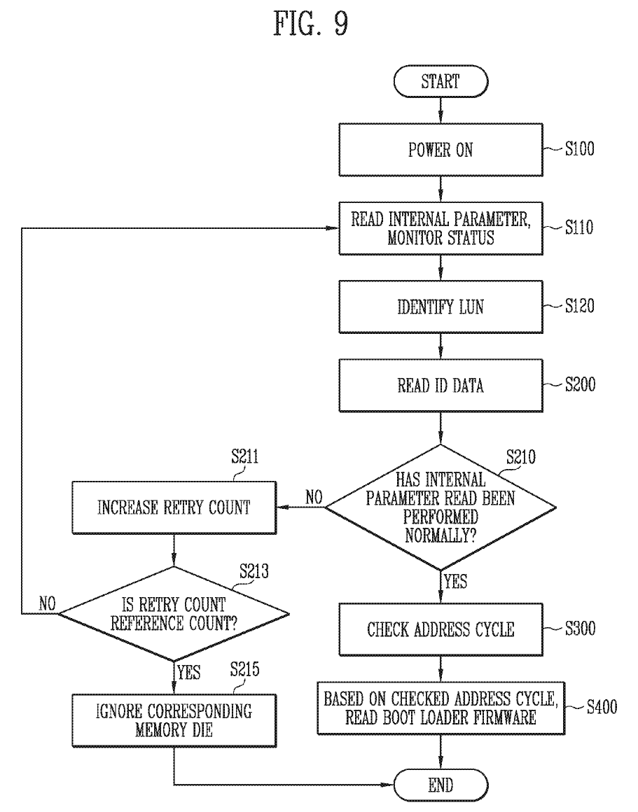

FIG. 9 is a flowchart illustrating a boot operation according to embodiments of the present disclosure.

Referring to FIG. 9, the processor 110 of FIG. 5 may perform booting of the memory device 200a according to a boot sequence.

Hereinafter, an operation in which the memory controller 100 performs booting of the memory device 200a among the plurality of memory devices 200 of FIG. 1 is described. Similarly, the memory controller 100 may perform booting of each of the plurality of memory devices 200.

Steps S100, S200, S300, and S400 of FIG. 9 may be similar to steps S100, S200, S300, and S400 of FIG. 6. Accordingly, repetitive descriptions may be omitted.

Also, for convenience of description, FIG. 9 illustrates only parts of the boot sequence which are related to the present disclosure. However, according to embodiments, the processor 110 may perform the booting of the memory device 200a by operations not illustrated in FIG. 9.

At step S100, power may be supplied to the memory controller 100 to activate the processor 110.

At step S110, the processor 110 may read an internal parameter (or a set value) of the memory device 200a, and may monitor a status of the memory device 200a. For example, the internal parameter may include a block status, a block size, a page size, error correction code information, a program/erase count (P/E count), or the like.

In embodiments, the processor 110 may read the internal parameter of the memory device 200a by a content addressable memory (CAM) read operation and optimize an operation of the memory device 200a based on the read internal parameter. A CAM read operation may perform content based retrieval based on data provided to the processor 110 and data stored within the memory device 200a.

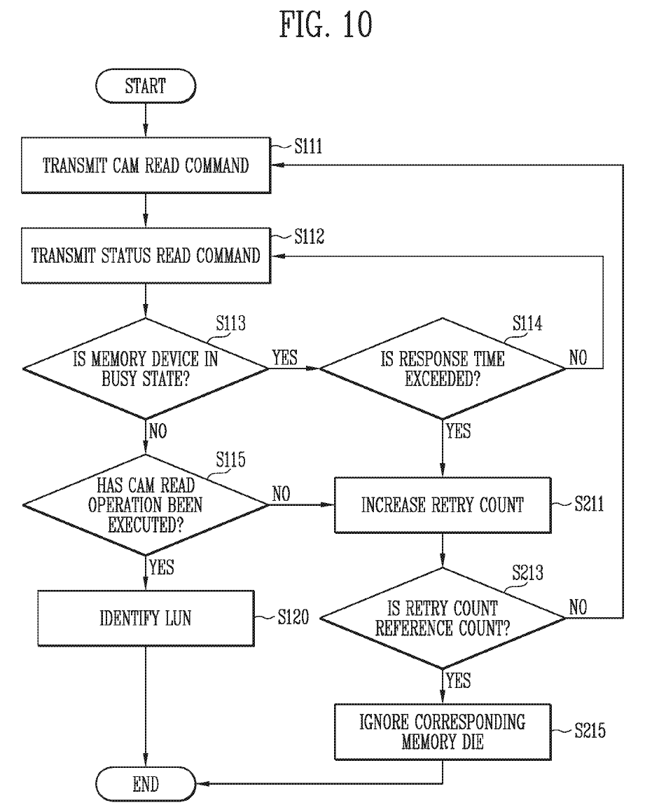

In addition, the processor 110 may determine whether a current status of the memory device 200a is normal by a status read operation, and may monitor whether the memory device 200a is ready to perform a new command from the memory controller 100, which allows the processor 110 to check whether the memory device 200a is operating normally and is in a bootable state. A detailed description of step S110 will be provided below with reference to FIG. 10.

At step S120, the processor 110 may identify a Logical Unit Number (LUN) which stores data used for booting. The LUN may be used to manage logical storage units (e.g., partitions) of the memory device 200a. In embodiments, the identified LUN may store boot loader firmware. For example, a memory block storing the boot loader firmware may be included in the identified LUN.

At step S200, the processor 110 may read ID data of the memory device 200a.

At step S210, the processor 110 may determine whether the CAM read operation at step S110 has been performed normally.

In embodiments, the processor 110 may check a bit of the first ID data to determine whether the CAM read operation has been performed normally. The first ID data may be included in the data signal received in the first cycle of the clock signal CLK of FIG. 2 among the data signals received in response to the read command.

For example, the processor 110 may determine that the CAM read operation has been performed normally when the first ID data is a reference command value. The processor 110 may determine that the CAM read operation has not been performed normally when the first ID data is not the reference command value. The reference command value may be ‘ADh’.

When it is determined that the CAM read operation has been performed normally, the processor 110 may perform step S300. When it is determined that the CAM read operation has not been performed normally, the processor 110 may perform step S211.

At step S300, the processor 110 may check the address cycle of the memory device 200a.

At step S211, the processor 110 may increase a retry count.

At step S213, the processor 110 may check whether the retry count is a reference count. When the retry count is not the reference count, the processor 110 may perform step S110, and when the retry count is the reference count, the processor 110 may perform step S215. For example, the reference count may be ‘5’.

At step S215, the processor 110 may ignore a particular memory die of which a retry count has reached the reference count. In embodiments, a particular memory die which fails to read an internal parameter may be excluded from a boot process. Accordingly, booting may be performed using only normal dies.

FIG. 10 is a flowchart illustrating an internal parameter read operation and a status monitoring operation according to embodiments of the present disclosure.

Referring to FIG. 10, the processor 110 of FIG. 5 may read the internal parameter of the memory device 200a and monitor the status of the memory device 200a.

Hereinafter, an operation in which the memory controller 100 performs booting of the memory device 200a among the plurality of memory devices 200 of FIG. 1 via the processor 110 is described. Similarly, the memory controller 100 may perform booting of each of the plurality of memory devices 200.

Further, steps S111 to S115 of FIG. 10 may be included in step S110 of FIG. 9. Further, steps S120, S211, S213, and S215 of FIG. 10 may be similar to steps S120, S211, S213, and S215 of FIG. 9. Accordingly, repetitive descriptions may be omitted.

At step S111, the processor 110 may transmit a CAM read command to the memory device 200a. In response to the CAM read command, the memory device 200a may output the internal parameter.

At step S112, the processor 110 may transmit a status read command to the memory device 200a. In response to the status read command, the memory device 200a may output status data including a current operation status.

A first status bit of the status data may indicate either a busy state, in which the memory device 200a is in operation and thus cannot perform another task, or a ready state, in which the memory device 200a can perform another task. The status data may be data received through the data bus of FIG. 2 in response to the status read command.

In embodiments, the memory device 200a may be in the busy state when the memory device 200a is performing the CAM read operation according to previous step S111. When the memory device 200a has completed the CAM read operation according to previous step S111, the memory device 200a may be in the ready state.

At step S113, the processor 110 may check whether the memory device 200a is in the busy state. In embodiments, the processor 110 may determine that the memory device 200a is in the busy state when a value of the first status bit is a first value, and the processor 110 may determine that the memory device 200a is in the ready state when the value of the first status bit is not the first value. For example, the status data may have a size of 1 byte, and the first status bit may be a particular bit of the status data. The first value may be ‘0’.

The processor 110 may perform step S114 when the memory device 200a is in the busy state, and may perform step S115 when the memory device 200a is not in the busy state.

At step S114, the processor 110 may check whether a response time is exceeded. By comparing a time during which the memory device 200a remains in the busy state with a reference time, the processor 110 may check whether the response time is exceeded. For example, the reference time may be 5 ms.

When the time during which the memory device 200a remains in the busy state exceeds the reference time, the processor 110 may determine that the response time is exceeded. When the time during which the memory device 200a remains in the busy state does not exceed the reference time, the processor 110 may determine that the response time is not exceeded.

The processor 110 may perform step S211 when the response time is exceeded, and may perform step S112 when the response time is not exceeded.

At step S115, the processor 110 may determine whether the CAM read operation has been executed. The processor 110 may determine whether the CAM read operation of the memory device 200a has been executed based on a value of a second status bit of the status data. The second status bit may be a bit at a different location in the status data than the first status bit. That is, the second status bit and the first status bit may be present at different locations in the status data.

The processor 110 may determine that the CAM read operation has been executed when the value of the second status bit is a second value. The processor 110 may determine that the CAM read operation has not been executed when the value of the second status bit is not the second value. The second value may be ‘1’.

In embodiments, step S210 of FIG. 9 may be a step of determining whether the CAM read operation has been performed normally, and step S115 of FIG. 10 may be a step of determining whether the CAM read operation has been executed.

The processor 110 may perform step S120 when the CAM read operation has been executed, and may perform step S211 when the CAM read operation has not been executed.

At step S211, the processor 110 may increase the retry count. The retry count may include the number of times the execution of the CAM read operation fails, the number of times the response time is exceeded, and the number of times the CAM read operation has not been performed normally.

At step S213, the processor 110 may check whether the retry count is the reference count. When the retry count is not the reference count, the processor 110 may perform step S112, and when the retry count is the reference count, the processor 110 may perform step S215.

At step S215, the processor 110 may ignore a particular memory die of which the retry count has reached the reference count.

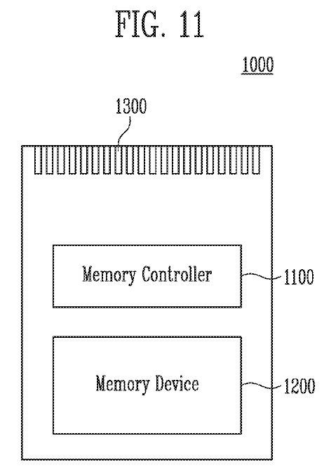

FIG. 11 is a block diagram illustrating a memory card system 1000 to which a storage device according to embodiments of the present disclosure is applied.

Referring to FIG. 11, the memory card system 1000 may include a memory controller 1100, a memory device 1200, and a connector 1300.

The memory controller 1100 may be coupled to the memory device 1200. The memory controller 1100 may be configured to access the memory device 1200. For example, the memory controller 1100 may be configured to control read, write, erase, and background operations of the memory device 1200. The memory controller 1100 may be configured to provide an interface between the memory device 1200 and a host. The memory controller 1100 may be configured to drive firmware for controlling the memory device 1200. The memory device 1200 may be implemented in the same manner as the memory devices 200 described with reference to FIG. 1.

For example, the memory controller 1100 may include components such as Random Access Memory (RAM), a processing unit, a host interface, a memory interface, and an error correction circuit.

The memory controller 1100 may communicate with an external device via the connector 1300. The memory controller 1100 may communicate with an external device (e.g., the host) based on a specific communication protocol. For example, the memory controller 1100 may communicate with the external device through at least one of various communication protocols such as a Universal Serial Bus (USB), a Multi-Media Card (MMC), an embedded MMC (eMMC), a Peripheral Component Interconnect (PCI), PCI-express (PCI-e), Advanced Technology Attachment (ATA), Serial-ATA (SATA), Parallel-ATA (PATA), a Small Computer System Interface (SCSI), an Enhanced Small Disk Interface (ESDI), Integrated Drive Electronics (IDE), Firewire, Universal Flash Storage (UFS), Wi-Fi, Bluetooth, and Non-Volatile Memory express (NVMe). For example, the connector 1300 may be defined by at least one of the various communication protocols described above.

For example, the memory device 1200 may be implemented as one of various non-volatile memory elements, such as Electrically Erasable and Programmable ROM (EEPROM), NAND flash memory, NOR flash memory, Phase-change RAM (PRAM), Resistive RAM (ReRAM), Ferroelectric RAM (FRAM), and Spin-Transfer Torque Magnetic RAM (STT-MRAM).

The memory controller 1100 and the memory device 1200 may be integrated into a single semiconductor device to form a memory card. For example, the memory controller 1100 and the memory device 1200 may be integrated into a single semiconductor device to form a memory card, such as a Personal Computer Memory Card International Association (PCMCIA), a Compact Flash (CF) card, a smart media card (SM, SMC), a memory stick, a Multi-Media Card (MMC, RS-MMC, MMCmicro, eMMC), an SD card (SD, miniSD, microSD, SDHC), or Universal Flash Storage (UFS).

According to embodiments, the memory controller 1100 may perform the boot operation described with reference to FIGS. 6, 7, 9, and 10. For example, the memory controller 1100 may check an address cycle set for the memory device 1200, and may read address data of a firmware block of the memory device 1200 based on the checked address cycle.

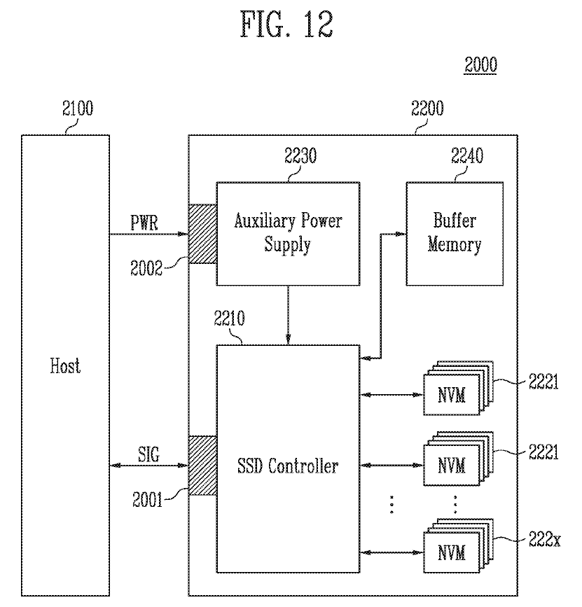

FIG. 12 is a block diagram illustrating an example of a Solid State Drive (SSD) system 2000 to which a storage device according to embodiments of the present disclosure is applied.

Referring to FIG. 12, the SSD system 2000 may include a host 2100 and an SSD 2200. The SSD 2200 may send and receive a signal SIG to and from the host 2100 via a signal connector 2001 and receive power PWR via a power connector 2002. The SSD 2200 may include an SSD controller 2210, a plurality of flash memories 2221 to 222x, an auxiliary power supply 2230, and a buffer memory 2240. x is a natural number greater than 1.

According to embodiments, the SSD controller 2210 may perform the boot operation described with reference to FIGS. 6, 7, 9, and 10. For example, the SSD controller 2210 may check an address cycle set for each of the plurality of flash memories 2221 to 222x, and may read address data of a firmware block in each of the plurality of flash memories 2221 to 222x based on the checked address cycle.

The SSD controller 2210 may control the plurality of flash memories 2221 to 222x in response to the signal SIG received from the host 2100. For example, the signal SIG may be based on an interface of the host 2100 and the SSD 2200. For example, the signal SIG may be defined by at least one of communication standards or interfaces, such as Universal Serial Bus (USB), Multi-Media Card (MMC), embedded MMC (eMMC), Peripheral Component Interconnect (PCI), PCI-express (PCI-e), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and Non-Volatile Memory express (NVMe) interfaces.

The auxiliary power supply 2230 may be coupled to the host 2100 via the power connector 2002. The auxiliary power supply 2230 may receive the power PWR from the host 2100 and may be charged. The auxiliary power supply 2230 may provide power of the SSD 2200 when the power supply from the host 2100 is not smooth. For example, the auxiliary power supply 2230 may be located within the SSD 2200 or may be located outside the SSD 2200. For example, the auxiliary power supply 2230 may be located on a main board and may provide auxiliary power to the SSD 2200.

The buffer memory 2240 may operate as a buffer memory for the SSD 2200. For example, the buffer memory 2240 may temporarily store data received from the host 2100 or data received from the plurality of flash memories 2221 to 222x, or may temporarily store metadata (e.g., a mapping table) of the plurality of flash memories 2221 to 222x. The buffer memory 2240 may include a volatile memory, such as DRAM, SDRAM, double data rate (DDR) SDRAM, low power double data rate (LPDDR) SDRAM, or graphics random access memory (GRAM), or a non-volatile memory, such as FRAM, ReRAM, STT-MRAM, or PRAM.

The embodiments disclosed herein are illustrative of the technical spirit of the present disclosure, not limiting the technical spirit of the present disclosure, and the scope of the technical spirit of the present disclosure is not limited by these embodiments. The scope of protection of this disclosure shall be construed by the appended claims, and all technical spirits within an equivalent scope shall be construed to be included within the scope of this disclosure.

Embodiments of the present disclosure may provide a memory controller capable of managing various memory devices by determining the number of cycles for receiving address information based on information set for a memory device, and a storage device including the memory controller.

What is claimed is:

1. A memory controller controlling a memory device including a plurality of memory blocks, wherein the memory controller is configured to:
read identification (ID) data stored in the memory device upon power-on;
check an address cycle set for the memory device based on the ID data; and
read, during the address cycle, address data of a firmware block in which boot loader firmware is stored, among the plurality of memory blocks.

2. The memory controller of claim 1, wherein the memory controller is configured to:
determine, based on the ID data, the address cycle to be a first cycle or a second cycle; and
read the address data during the determined address cycle.

3. The memory controller of claim 2, wherein the memory controller is configured to:
compare a bit value of an address field of the ID data with a reference bit value; and
determine the address cycle to be the first cycle or the second cycle based on the comparison.

4. The memory controller of claim 3, wherein the memory controller is configured to:
determine the first cycle as the address cycle when the bit value of the address field is identical to the reference bit value; and
determine the second cycle as the address cycle when the bit value of the address field is not identical to the reference bit value.

5. The memory controller of claim 4,
wherein the memory controller is configured to:
output a clock signal to the memory device; and
read the address data from the memory device in units of 1 byte for each cycle of the clock signal, and
wherein the address cycle is a number of cycles of the clock signal used for the memory controller to read the address data.

6. The memory controller of claim 5, wherein the memory controller is configured to:
read, when the address cycle is the first cycle, the address data over a number of cycles of the clock signal of the first cycle; and
read, when the address cycle is the second cycle, the address data over a number of cycles of the clock signal of the second cycle.

7. The memory controller of claim 6, wherein the memory controller is configured to:
access the firmware block based on the address data;
read the boot loader firmware stored in the firmware block; and
boot the memory device based on the boot loader firmware.

8. The memory controller of claim 7,
wherein the memory controller is configured to output a read command for reading the ID data to the memory device, and
wherein the ID data is included in a data signal received in a third cycle of the clock signal among data signals received in response to the read command.

9. The memory controller of claim 8, wherein the address field is one of a plurality of fields included in the ID data.

10. The memory controller of claim 9, wherein the address field is a last field of the plurality of fields.

11. A storage device comprising:
a plurality of memory devices; and
a memory controller configured to read, upon power-on, address data of a memory block in which boot loader firmware of each of the plurality of memory devices is stored, according to an address cycle set for each of the plurality of memory devices.

12. The storage device of claim 11, wherein the address cycle for each of the plurality of memory devices is set to be a first cycle or a second cycle.

13. The storage device of claim 12, wherein the memory controller is configured to:
read, for a first memory device for which a first address cycle is set, among the plurality of memory devices, first address data of a memory block in which boot loader firmware of the first memory device is stored during the first address cycle; and
read, for a second memory device for which a second address cycle is set, among the plurality of memory devices, second address data of a memory block in which boot loader firmware of the second memory device is stored during the second address cycle.

14. The storage device of claim 13, wherein the memory controller is configured to:
read first ID data stored in the first memory device during the power-on; and
check, based on the first ID data, the first address cycle set for the first memory device.

15. The storage device of claim 14, wherein the memory controller is configured to:
compare a bit value of an address field of the first ID data with a reference bit value; and
determine the first address cycle to be the first cycle or the second cycle.

16. The storage device of claim 15, wherein the memory controller is configured to:
determine the first cycle as the first address cycle when the bit value of the address field is identical to the reference bit value; and
determine the second cycle as the first address cycle when the bit value of the address field is not identical to the reference bit value.

17. The storage device of claim 16,
wherein the memory controller is configured to:
output a clock signal to the first memory device; and
read the first address data from the first memory device in units of 1 byte for each cycle of the clock signal, and
wherein the first address cycle is a number of cycles of the clock signal used for the memory controller to read the first address data.

18. The storage device of claim 17, wherein the memory controller is configured to:
read, when the first address cycle is the first cycle, the first address data over a number of cycles of the clock signal of the first cycle; and
read, when the first address cycle is the second cycle, the first address data over a number of cycles of the clock signal of the second cycle.

19. The storage device of claim 18, wherein the memory controller is configured to:
access, based on the read first address data, the memory block in which the boot loader firmware of the first memory device is stored;
read the boot loader firmware stored in the memory block; and
boot the first memory device based on the boot loader firmware.

20. The storage device of claim 19,
wherein the memory controller is configured to output a read command for reading the first ID data to the first memory device, and
wherein the first ID data is included in a data signal received in a third cycle of the clock signal among data signals received in response to the read command.
